(19) United States
(12) Patent Application Publication
(10) Pub. No.: US 2025/0361594 A1
(43) Pub. Date: Nov. 27, 2025

(54) METHOD OF COATING A SUBSTRATE INCLUDING A MULTI-LAYER COATING

(71) Applicant: Applied Materials, Inc., Santa Clara, CA (US)

(72) Inventors: Laksheswar Kalita, San Jose, CA (US); Joseph Frederick Behnke, San Jose, CA (US); Nitin K. Ingle, San Jose, CA (US); Christopher Beaudry, San Jose, CA (US); Jonathan Strahle, Santa Clara (CA); Sanni Seppaelae, Santa Clara, CA (US)

(21) Appl. No.: 19/206,441

(22) Filed: May 13, 2025

Related U.S. Application Data
(60) Provisional application No. 63/650,707, filed on May 22, 2024.

(51) Int. Cl. C23C 14/02; C23C 14/06; C23C 14/08; C23C 14/22; C23C 14/54; C23C 16/02; C23C 16/08; C23C 16/40; C23C 16/453; C23C 16/455

(52) U.S. Cl. CPC C23C 14/021; C23C 14/0694; C23C 14/081; C23C 14/228; C23C 14/542; C23C 16/0227; C23C 16/08; C23C 16/403; C23C 16/453; C23C 16/45525

(57) ABSTRACT

Described herein is a method for forming a multi-layer coating including a first layer comprising a metal oxide layer on a surface of a chamber component and a second layer comprising a rare earth fluoride layer on the metal oxide layer. The method further includes removing surface oxidation on the rare earth fluoride layer using a wet clean process.

### CROSS REFERENCE TO RELATED APPLICATION(S)

The present application claims priority to U.S. Provisional Patent Application No. 63/650,707 filed on May 22, 2024. The entire contents of which are incorporated in its entirety.

### TECHNICAL FIELD

Embodiments of the disclosure relate to articles, coated chamber components and methods of coating chamber components with a plasma resistant coating. The plasma resistant coating includes a dual layer including a first layer comprising a metal oxide layer and a second layer comprising a rare earth layer.

### BACKGROUND

Various manufacturing processes expose semiconductor process chamber components to high temperatures, high energy plasma, a mixture of corrosive gases, high stress, and combinations thereof. These extreme conditions may erode and/or corrode the chamber components, increasing the chamber components' susceptibility to defects. It is desirable to reduce these defects and improve the components' erosion and/or corrosion resistance in such extreme environments.

To minimize the effects of corrosive plasma, chamber components may be coated with plasma resistant spray coatings. However, such coatings may react with a fluorine based plasma, which can affect process performance.

### SUMMARY

Described in embodiments herein is a method comprising depositing a multi-layer coating. The method includes depositing a first layer including a metal oxide on a surface of a chamber component. The method further includes a second layer including a rare earth fluoride on the first layer. Then, any surface oxidation is removed from the rare earth fluoride by using a wet clean process.

### BRIEF DESCRIPTION OF THE DRAWINGS

The present disclosure is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 depicts a sectional view of one embodiment of a processing chamber;

FIG. 2 depicts one embodiment of an atomic layer deposition process described herein.

FIG. 3A depicts a deposition mechanism applicable to a variety of deposition techniques utilizing energetic particles such as ion assisted deposition (IAD).

FIG. 3B depicts a schematic of an IAD deposition apparatus.

FIG. 4 is a flow chart illustrating a method of providing the coating according to an embodiment of the present disclosure.

FIG. 5 is a flow chart illustrating a method of cleaning and coating according to an embodiment of the present disclosure.

### DETAILED DESCRIPTION

Embodiments described herein provide an article such as a showerhead or other chamber component for a processing chamber having a coating including multiple layers. The multi-layer coating includes a first layer comprising a metal oxide (e.g., aluminum oxide) and a second layer comprising a rare earth fluoride (e.g., a yttrium-containing fluoride layer). The coating may include bi-layers or layers that includes alternating stacks of a metal oxide layer and a rare earth metal-containing fluoride layer. The article may include a metal, a polymer, a ceramic, or a combination thereof. The deposition process used to form the metal oxide layer and/or the rare earth fluoride layer may be an atomic layer deposition (ALD) process, a chemical vapor deposition (CVD) process, an ion assisted deposition (IAD), or an physical vapor deposition (PVD), but is not limited to these processes.

The coating of the present disclosure may provide plasma corrosion resistance for protection of the article. The coating may also not be reactive to fluorine based chemistries. The coating may also reduce any defects of the article and/or chamber component. The multi-layer coating of the present disclosure protects chamber components from corrosion in processing chambers when components containing these materials are exposed to plasmas and/or other reactive chemicals. The improved corrosion resistance provided by the coating may improve the service life of the article, while reducing maintenance and manufacturing cost. Additionally, the coating may not cause a shift in process results of processes using fluorine based chemistries, e.g. NF₃.

The multi-layer coating as described herein not only provides plasma resistance to the chamber component but also reduces oxygen on the surface. Oxygen formation within the surface of fluoride coatings has been found to negatively affect the performance of the process chamber during etching processes, such as plasma etching. The coating further reduces the presence of any other contaminants, such as alkali metals (e.g., sodium or potassium) that may be present in the rare earth fluoride layer. Therefore, the method as described herein further includes a cleaning step to remove any oxygen or alkali metals from the surface of the rare earth fluoride coating and/or chamber component to improve the life cycle of the chamber components and effectiveness of the coating. The multi-layer coating as described herein improves performance of the process chamber components and it has been found that the coating is more resistant to radicals and/or oxygen formation as compared to a rare earth fluoride coating for which surface oxygen molecules have not been removed. Such oxygen molecules may naturally form on the rare earth fluoride coating during and/or after deposition. The cleaning process has been found to also remove any trace alkali metals or other contaminants that can cause film impurity and/or device failure in a processing chamber. Thus, the method as described herein improves the overall life cycle of the chamber component.

It has been found that the multi-layer coating according to embodiments of the present disclosure reduces defects during etch processes and may provide chemical and/or etch resistance in plasma environments. The combination of the metal oxide layer and rare earth fluoride having an oxygen-free (or near oxygen-free) surface was found to improve the corrosion resistance and performance of the coated chamber components.

In some embodiments, the multi-layer coating may be formed via atmospheric pressure plasma spray (APPS), low pressure plasma spray (LPPS), suspension plasma spray (SPS), ion assisted deposition (IAD), chemical vapor deposition (CVD), atomic layer deposition (ALD), magnetron sputtering physical vapor deposition (MSPVD), physical vapor deposition (PVD), plasma enhanced chemical vapor deposition (PECVD), plasma enhanced atomic layer deposition (PEALD), or another deposition technique.

In some embodiments, the coated article may include a semiconductor process chamber component or process chamber component for other manufacturing processes (e.g., for display, photovoltaics, etc.). Examples of process chamber components include a lid, a showerhead, a nozzle, a chuck (e.g., an electrostatic chuck), a chamber liner, a window, a heater, and so on.

“Plasma resistant material” refers to a material that is resistant to erosion and corrosion due to exposure to plasma processing conditions. The plasma processing conditions include a plasma generated from halogen-containing gases, such as C₂F₆, SF₆, SiCl₄, HBR, NF₃, CF₄, CHF₃, CH₂F₃, F, NF₃, Cl₂, CCl₄, BCl₃ and SiF₄, among others, and other gases such as O₂, or N₂O.

When the terms “about” and “approximately” are used herein, these are intended to mean that the nominal value presented is precise within ±10%. Some embodiments are described herein with reference to chamber components and other articles installed in plasma etchers for semiconductor manufacturing. However, it should be understood that such plasma etchers may also be used to manufacture micro-electro-mechanical systems (MEMS)) devices. Additionally, the articles described herein may be other structures that are exposed to plasma or other corrosive environments. Articles discussed herein may be chamber components for processing chambers such as semiconductor processing chambers. For example, the articles may be chamber components for a plasma etcher, a plasma cleaner, a plasma propulsion system, or other processing chambers. Examples of chamber components that may benefit from embodiments of the invention include a substrate support assembly, an electrostatic chuck (ESC), a ring (e.g., a process kit ring or single ring), a chamber wall, a base, a gas distribution plate, a face plate, a showerhead, a nozzle, a lid, a liner, a liner kit, a shield, a plasma screen, a flow equalizer, a cooling base, a chamber viewport, a chamber lid, and so on.

Moreover, embodiments are described herein with reference to multi-layer coatings and a method of depositing the multi-layer coating that protect the chamber component when used in a process chamber for plasma rich processes. However, it should be understood that the multi-layer coatings may also provide improvement in plasma resistance when used in process chambers for other processes such as non-plasma etchers, non-plasma cleaners, chemical vapor deposition (CVD) chambers physical vapor deposition (PVD) chambers, plasma enhanced chemical vapor deposition (PECVD) chambers, plasma enhanced physical vapor deposition (PEPVD) chambers, plasma enhanced atomic layer deposition (PEALD) chambers, and so forth. Additionally, the techniques discussed herein with regards to formation of coating include dual layers are also applicable to articles other than chamber components for processing chambers.

In some embodiments, the deposition or formation process to prepare the coating of the present disclosure may be an atomic layer deposition (ALD), but it should be understood that that other deposition or formation processes may be used such as a plasma spray process, ion assisted deposition (IAD), electron beam ion assisted deposition (EB-IAD), chemical vapor deposition, or physical vapor deposition.

The coating of the present disclosure may include a bi-layer, or a dual layer, stack or a plurality of alternating layers stack. The bi-layer stack or plurality of alternating layers stack may include one or more layers of a metal oxide, e.g. Al₂O₃, and one or more layers of a rare earth fluoride, e.g. YF₃. The coating may include one or more interruption layer. The thickness of each metal oxide layer may be about 10 nm to about 50 nm. The thickness of each rare earth compound layer may be about 15 nm to about 20 micron. In some embodiments, the coating may have conformal coverage of the underlying surface that is coated (including coated surface features) with a uniform thickness variation from pone part of the coating to another of less than about +/−20%, a thickness variation of +/−10%, a thickness variation of +/−5%, or a lower thickness variation.

ALD allows for a controlled deposition of material through chemical reactions with the surface of the article. Aside from being a conformal process, ALD is also a uniform process and is capable of forming very thin films, for example, having a thickness of about 3 nm or more. For ALD, the final thickness of material is dependent on the number of reaction cycles that are run, because each reaction cycle will grow a layer of a certain thickness that may be one atomic layer or a fraction of an atomic layer. A typical reaction cycle of an ALD process starts with a precursor (i.e, a single chemical A) flooded into an ALD chamber and adsorbed onto the surface of the article. The excess precursor is then flushed out of the ALD chamber before a reactant (i.e. a single chemical R) is introduced into the ALD chamber and subsequently flushed out. The interruption layer may include a metal oxide. Excess precursors are flushed out. A reactant is introduced into the ALD chamber and reacts with the adsorbed precursors to form a solid layer before the excess chemicals are flushed out. For ALD, the final thickness of material is dependent on the number of reaction cycles that are run, because each reaction cycle will grow a layer of a certain thickness that may be one atomic layer or a fraction of an atomic layer.

The ALD technique can deposit a thin layer of material at a relatively low temperature (e.g., about 25° C. to about 200° C.) so that it does not damage or deform the component. For example, components such as an insulator plate that are composed of materials such as polystyrene may be damaged at temperatures above about 200° C. Additionally, the ALD technique can also deposit a layer of material within porous materials (i.e., on the pore walls of the pores within a porous material). Additionally, the ALD technique may produce relatively thin (i.e., 1 μm or less) coatings that are porosity-free (i.e., pin-hole free), which may eliminate crack formation during deposition. The surface of the porous component may be coated in a manner that covers and plugs the pores and reduces or eliminates the permeability of the porous component.

CVD allows for deposition of a highly dense, pure, and uniform coating with good reproducibility and adhesion at high deposition rates. A typical reaction cycle of CVD may comprise: generating precursors from a starting material, transporting the precursors into a reaction chamber, absorbing the precursors onto a heated article, chemically reacting the precursor with the surface of the article to be coated to form a deposit and a gaseous by-product, and removing the gaseous by-product and unreacted gaseous precursors from the reaction chamber.

Additionally, the ALD and CVD techniques produce relatively thin (e.g., 10 μm or less) coatings that are porosity-free (i.e., pin-hole free), which may eliminate crack formation during deposition. The term “porosity-free” as used herein means absence of any pores, pin-holes, voids, or cracks along the whole depth of the coating as measured by transmission electron microscopy (TEM).

The multi-layer coatings may be deposited on a variety of articles. In some embodiments, process chamber components, such as an electrostatic chuck, a nozzle, a gas distribution plate, a showerhead, an electrostatic chuck component, a chamber wall, a liner, a liner kit, a gas line, a lid, a chamber lid, a nozzle, a single ring, a processing kit ring, a base, a shield, a plasma screen, a flow equalizer, a cooling base, a chamber viewport, a bellow, a faceplate, selectivity modulating device, plasma generation units (e.g., radiofrequency electrodes with housings), and diffusers, would benefit from having these plasma resistant protective coatings to protect the components in harsh environments with corrosive plasmas.

Examples of processing gases that may be used to process substrates in the processing chamber include halogen-containing gases, such as C₂F₆, SF₆, SiCl₄, HBr, NF₃, CF₄, CHF₃, CH₂F₃, F, NF₃, Cl₂, CCl₄, BCl₃ and SiF₄, among others, and other gases such as O₂, or N₂O. Examples of carrier gases include N₂, He, Ar, and other gases inert to process gases (e.g., non-reactive gases).

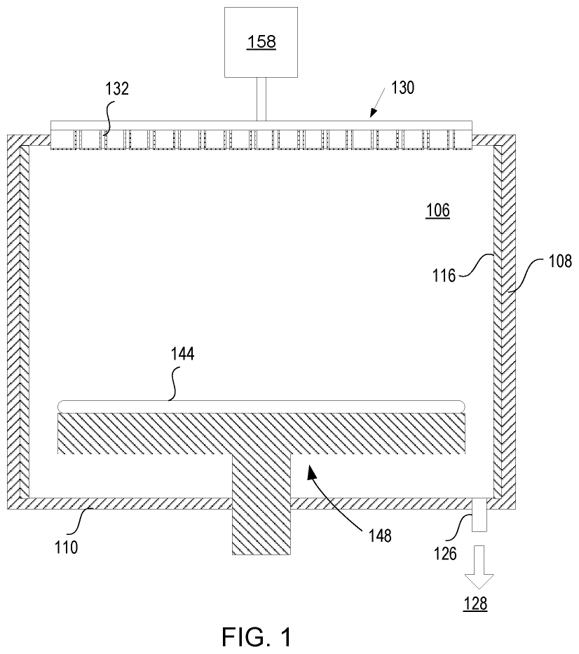

Referring now to the figures, FIG. 1 is a sectional view of a processing chamber 100 (e.g., a semiconductor processing chamber) having one or more chamber components in accordance with embodiments of the present disclosure. The processing chamber 100 may be used for processes in which a corrosive plasma environment and/or corrosive chemistry is provided. For example, the processing chamber 100 may be a chamber for a plasma etch reactor (also known as a plasma etcher). Examples of chamber components that may be exposed to plasma in the processing chamber 100 are a substrate support assembly 148, an electrostatic chuck (ESC), a ring (e.g., a process kit ring or single ring), a chamber wall, a base, a showerhead 130, a gas distribution plate, a liner, a liner kit, a shield, a plasma screen, a flow equalizer, a cooling base, a chamber viewport, a chamber lid, a nozzle, process kit rings, and so on. In embodiments, processing chamber 100 is used to perform an etch process on a patterned substrate that includes a plurality of trenches formed thereon.

In one embodiment, the processing chamber 100 includes a chamber body 102 and a showerhead 130 that enclose an interior volume 106. The showerhead 130 may or may not include a gas distribution plate. For example, the showerhead may be a multi-piece showerhead that includes a showerhead base and a showerhead gas distribution plate bonded to the showerhead base. Alternatively, the showerhead 130 may be replaced by a lid and a nozzle in some embodiments, or by multiple pie shaped showerhead compartments and plasma generation units in other embodiments. The chamber body 102 may be fabricated from aluminum, stainless steel or other suitable material. The chamber body 102 generally includes sidewalls 108 and a bottom 110. Any of the showerhead 130 (or lid and/or nozzle), sidewalls 108 and/or bottom 110 may include the multi-layer plasma resistant coating.

An outer liner 116 may be disposed adjacent the sidewalls 108 to protect the chamber body 102. The outer liner 116 may be a halogen-containing gas resist material such as Al₂O₃ or Y₂O₃. The outer liner 116 may be coated with the multi-layer plasma resistant ceramic coating in some embodiments.

An exhaust port 126 may be defined in the chamber body 102, and may couple the interior volume 106 to a pump system 128. The pump system 128 may include one or more pumps and throttle valves utilized to evacuate and regulate the pressure of the interior volume 106 of the processing chamber 100.

The showerhead 130 may be supported on the sidewalls 108 of the chamber body 102 and/or on a top portion of the chamber body. The showerhead 130 (or lid) may be opened to allow access to the interior volume 106 of the processing chamber 100, and may provide a seal for the processing chamber 100 while closed. A gas panel 158 may be coupled to the processing chamber 100 to provide process and/or carrier gases to the interior volume 106 through the showerhead 130 or lid and nozzle. Examples of process gas that may be delivered by the gas panel 158 and used to process substrates/samples in the processing chamber 100 include a silicon containing gas, halogen-containing gases, such as C₂F₆, SF₆, HBr, NF₃, CF₄, CHF₃, CH₂F₃, F, NF₃, Cl₂, CCl₄, BCl₃ and SiF₄, among others, and other gases such as O₂ or N₂O. Examples of carrier gases (also referred to herein as a diluent) include N₂, He, Ar, and other gases inert to process gases (e.g., non-reactive gases). The showerhead 130 includes multiple gas delivery holes 132 throughout the showerhead 130. The showerhead 130 may be or may include aluminum, anodized aluminum, an aluminum alloy (e.g., Al 6061), or an anodized aluminum alloy. In some embodiments, the showerhead includes a gas distribution plate (GDP) bonded to the showerhead. The GDP may be, for example, Si or SiC. The GDP may additionally include multiple holes that line up with the holes in the showerhead.

A substrate support assembly 148 is disposed in the interior volume 106 of the processing chamber 100 below the showerhead 130. The substrate support assembly 148 holds a substrate 144 (e.g., a wafer) during processing. The substrate support assembly 148 may include an electrostatic chuck that secures the substrate 144 during processing, a metal cooling plate bonded to the electrostatic chuck, and/or one or more additional components. An inner liner may cover a periphery of the substrate support assembly 148. The inner liner may be a halogen-containing gas resist material such as Al₂O₃ or Y₂O₃. The substrate support assembly, portions of the substrate support assembly, and/or the inner liner may be coated with the metal layer and barrier layer in some embodiments.

The processing chamber 100 may be an etch chamber. In embodiments, the etch process is performed to selectively etch films disposed on surfaces of the substrate 144. For example, the substrate 144 may be a semiconductor wafer, a glass plate, a SiGe wafer, or another type of substrate.

Any of the aforementioned components of the processing chamber 100 may be coated with the multi-layer coating described herein. For example, any of the aforementioned components of processing chamber 100 may include an Al₂O₃ layer and a YF₃ layer over the Al₂O₃ layer, where a surface of the YF₃ layer has been treated using an acid bath to remove oxygen molecules from the surface of the YF₃ layer and increase a purity of the YF₃ layer.

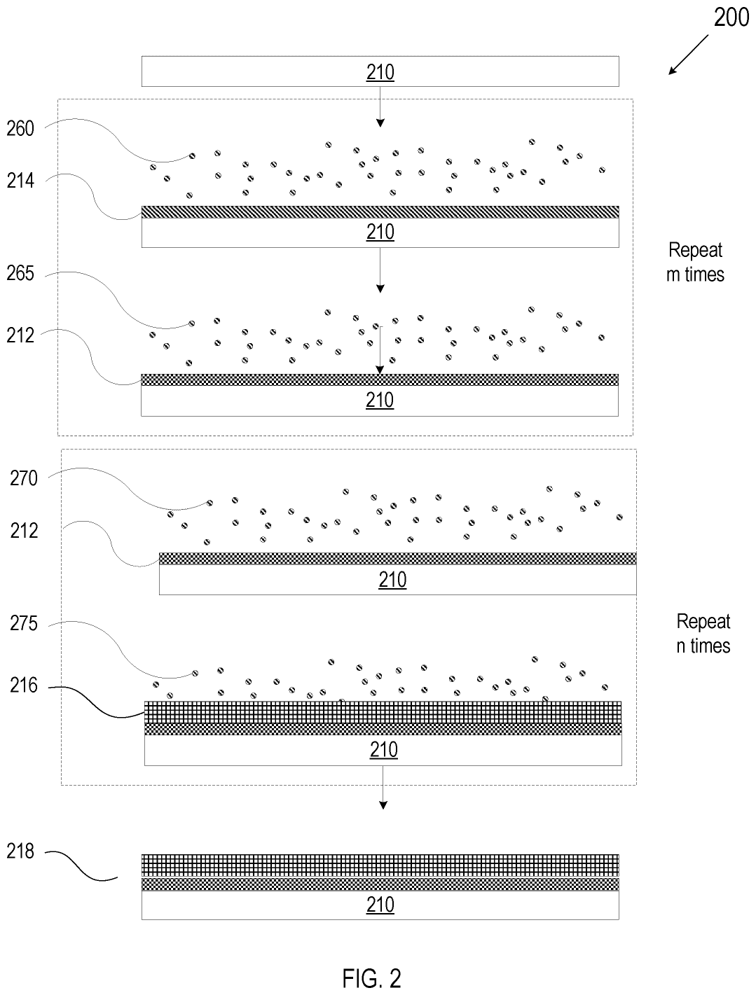

FIG. 2 illustrates an ALD deposition process to form a multi-layer coating on an article 210 having a surface. Article 210 may represent various process chamber components (e.g., semiconductor process chamber components) including but not limited to an electrostatic chuck, a nozzle, a gas distribution plate, a showerhead, an electrostatic chuck component, a chamber wall, a liner, a liner kit, a gas line, a lid, a chamber lid, a nozzle, a single ring, a processing kit ring, a base, a shield, a plasma screen, a flow equalizer, a cooling base, a chamber viewport, a bellow, a faceplate, selectivity modulating device, and so on. The article 210 may be made from a metal (such as aluminum, stainless steel), a ceramic (such as Y₂O₃, Al₂O₃, Y₃Al₅O₁₂ (YAG), and so forth), a metal-ceramic composite, a polymer, a polymer ceramic composite, mylar, polyester, or other suitable materials, and may further comprise materials such as AlN, Si, SiC, Al₂O₃, SiO₂, and so on.

For ALD, either adsorption of a precursor onto a surface or a reaction of a reactant with the adsorbed precursor may be referred to as a “half-reaction.” During a first half reaction, a precursor is pulsed onto the surface of the article 210 (or onto a layer formed on the article 210) for a period of time sufficient to allow the precursor to fully adsorb onto the surface. The adsorption is self-limiting as the precursor will adsorb onto a finite number of available sites on the surface, forming a uniform continuous adsorption layer on the surface. Any sites that have already adsorbed a precursor will become unavailable for further adsorption with the same precursor unless and/or until the adsorbed sites are subjected to a treatment that will form new available sites on the uniform continuous coating. Exemplary treatments may be plasma treatment, treatment by exposing the uniform continuous adsorption layer to radicals, or introduction of a different precursor able to react with the most recent uniform continuous layer adsorbed to the surface.

The excess precursors are pumped out until an oxygen-containing reactant is injected to react with the adsorbents to form a single metal oxide layer (e.g., of Al₂O₃). This fresh layer is ready to adsorb the precursors in the next cycle. In some embodiments, ALD is performed to grow a metal oxide layer, and then to grow a rare earth fluoride layer. The metal oxide layer is grown

In FIG. 2, article 210 may be introduced to a first precursor 260 for a first duration until a surface of article 210 is fully adsorbed with the first precursor 260 to form an adsorption layer 214. Subsequently, article 210 may be introduced to a first reactant 265 to react with the adsorption layer 214 to grow a metal oxide layer 212 (e.g., so that the metal oxide layer 212 is fully grown or deposited. The first precursor 260 may be a metal, such as aluminum and the first reactant 265 may be an oxygen source such as H₂O, O₃, etc. to form the metal oxide layer 212. Multiple additional deposition cycles may be performed (e.g., each including exposing the article to the first precursor and the first reactant) to increase a thickness of the metal oxide layer 212.

After forming the metal oxide layer 212, a second precursor 270 is introduced for a second duration to cause a first half reaction and form a rare earth adsorption layer. A second reactant may then be introduced for a third duration to form a second half reaction with the adsorption layer to form a rare-earth fluoride layer 216 on the metal oxide layer 212 (e.g., so that the rare-earth fluoride layer 216 is fully grown or deposited, where the terms grown and deposited may be used interchangeably herein). The second precursor 270 may be a precursor for yttrium or another metal, for example. The second reactant 275 may be fluorine, or a fluoride source. Accordingly, ALD may be used to form the rare-earth fluoride layer 216.

Rare-earth fluoride layer 216 may be uniform, continuous and conformal. The rare-earth fluoride layer 216 may be porosity free (e.g., have a porosity of 0) or have an approximately 0 porosity in embodiments (e.g., a porosity of 0% to 0.01%). Layer 216 may have a thickness of less than one atomic layer to a few atoms in some embodiments after a single ALD deposition cycle. Some metalorganic precursor molecules are large. The rare-earth fluoride layer 216 of the present disclosure is found to have at least about 95%, at least 98%, or at least 99% purity.

Multiple full ALD deposition cycles may be implemented to deposit a thicker rare-earth fluoride layer 216 or thicker metal oxide layer 212, with each full cycle for a metal oxide layer or a rare earth fluoride layer adding to the thickness by an additional fraction of an atom to a few atoms. As shown, up to m full cycles may be performed to grow the metal oxide layer 212 and/or up to n full cycles may be performed to form the rare-earth fluoride layer 216, where n and m are an integer values greater than 1. In embodiments, rare-earth fluoride layer 216 may have a thickness of about 15 nm to about 20 microns. In embodiments, metal oxide layer 212 may have a thickness of about 10 nm to about 50 nm. After each of the metal oxide layer 212 and rare-earth fluoride layer is formed on the substrate, the multi-layer coating 218 is formed.

Since ALD is used for the deposition, the internal surfaces of high aspect ratio features such as gas delivery holes in a showerhead or a gas delivery line may be coated, and thus an entirety of a component may be protected from exposure to a corrosive environment. Layer 216 may be YF₃.

In some embodiments, article 210 having layer 216 and layer 212 may be repeated to form additional layers on the article 210. In some embodiments, the metal oxide layer 212 may also be referred to as an interruption layer.

The metal oxide layer 212 may be uniform, continuous and conformal. The metal oxide layer 212 may have a very low porosity of less than 1% in embodiments, and less than 0.1% in further embodiments, and about 0% in embodiments or porosity-free in still further embodiments.

A ratio of the rare-earth fluoride layer thickness to the metal oxide layer thickness may be about 5000:1 to about 1:1 or about 2500:1. The ratio of rare-earth fluoride layer to the interruption layer may be such that the protective coating provides improved corrosion and erosion resistance as well as improved resistance to cracking and/or delamination caused by chamber processing. The thickness ratio may be selected in accordance with specific chamber applications.

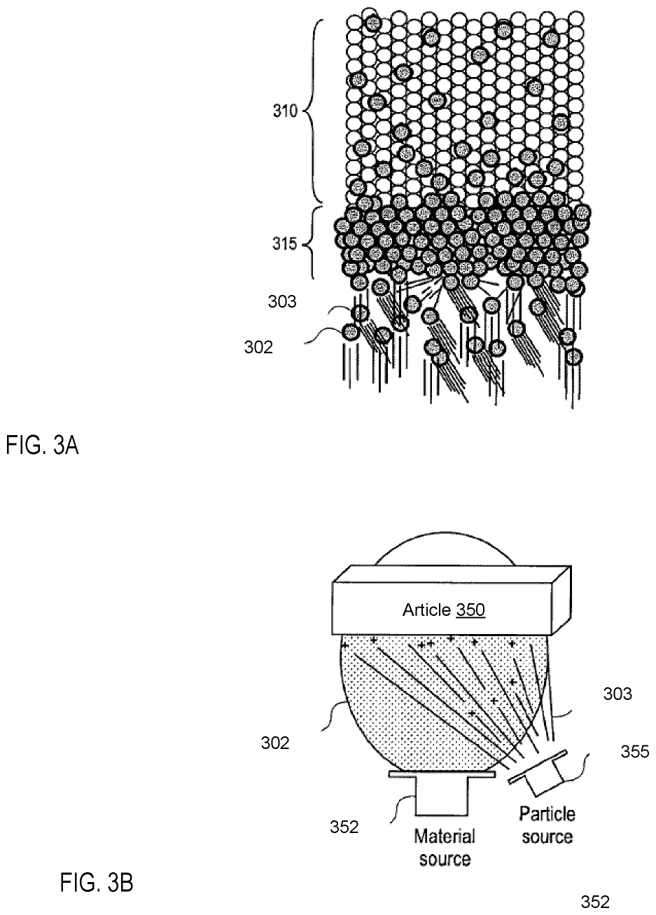

FIG. 3A depicts a deposition mechanism applicable to a variety of deposition techniques utilizing energetic particles such as ion assisted deposition (IAD). Exemplary IAD methods include deposition processes which incorporate ion bombardment, such as evaporation (e.g., activated reactive evaporation (ARE) or electron beam ion assisted deposition (EB-IAD)) and sputtering (e.g., ion beam sputtering ion assisted deposition (IBS-IAD)) in the presence of ion bombardment to form plasma resistant coatings as described herein. EB-IAD may be performed by evaporation. IBS-IAD may be performed by sputtering a solid target material (e.g., a solid metal target). Any of the IAD methods may be performed in the presence of a reactive gas species, such as O₂, N₂, halogens, etc.

As shown, the thin film protective layer 315 is formed by an accumulation of deposition materials 302 in the presence of energetic particles 303 such as ions. The deposition materials 302 include atoms, ions, radicals, or their mixture. The energetic particles 303 may impinge and compact the thin film protective layer 315 as it is formed.

In one embodiment, IAD is utilized to form the coating 315, as previously described elsewhere herein. FIG. 3B depicts a schematic of an IAD deposition apparatus. As shown, a material source 352 provides a flux of deposition materials 302 while an energetic particle source 355 provides a flux of the energetic particles 303, both of which impinge upon the article 350 throughout the IAD process. The energetic particle source 355 may be an Oxygen, Fluorine or other ion source. The energetic particle source 355 may also provide other types of energetic particles such as inert atom, radicals, neutron atoms, and/or nano-sized particles which come from particle generation sources (e.g., from plasma, reactive gases or from the material source that provide the deposition materials). The material source (e.g., a target body) 352 used to provide the deposition materials 302 may be a bulk sintered ceramic corresponding to the same ceramic that the coating 315 is to be composed of. For example, the material source may be a bulk sintered YF₃.

IAD may utilize one or more plasmas or beams to provide the material and energetic ion sources. Reactive species may also be provided during deposition of the plasma resistant coating. In one embodiment, the energetic particles 303 include at least one of non-reactive species (e.g., Ar) or reactive species (e.g., O). In further embodiments, reactive species such as CO and halogens (Cl, F, Br, etc.) may also be introduced during the formation of a plasma resistant coating to further increase the tendency to selectively remove deposited material most weakly bonded to the coating 315.

With IAD processes, the energetic particles 303 may be controlled by the energetic ion (or other particle) source 355 independently of other deposition parameters. According to the energy (e.g., velocity), density and incident angle of the energetic ion flux, composition, structure, crystalline orientation and grain size of the thin film protective layer may be manipulated. Additional parameters that may be adjusted are a temperature of the article during deposition as well as the duration of the deposition.

The ion assist energy is used to densify the coating and to accelerate the deposition of the material on the surface of the substrate. Ion assist energy can be varied using both the voltage and current of the ion source. The voltage and current can be adjusted to achieve high and low coating density, to manipulate a stress of the coating and also a crystallinity of the coating. The ion assist energy may range from approximately 50-500 V and approximately 1-50 amps (A). The ion assist energy can also be used to intentionally change a stoichiometry of the coating. For example, a metallic target can be used during deposition, and converted to a metal oxide.

Coating temperature can be controlled by using heaters to heat a deposition chamber and/or a substrate and by adjusting a deposition rate. Substrate (article) temperature during deposition may be roughly divided into low temperature (around 120-150° C. in one embodiment which is typical room temperature) and high temperature (around 270° C. or above in one embodiment). Deposition temperature can be used to adjust film stress, crystallinity, and other coating properties.

A working distance is a distance between the electron beam (or ion beam) gun and the substrate. The working distance can be varied to achieve a coating with a highest uniformity. Additionally, working distance may affect deposition rate and density of the coating.

A deposition angle is the angle between the electron beam (or ion beam) and the substrate. Deposition angle can be varied by changing the location and/or orientation of the substrate. By optimizing the deposition angle, a uniform coating in three dimensional geometries can be achieved.

EB-IAD and IBS-IAD depositions are feasible on a wide range of surface conditions. However, polished surfaces are preferred to achieve a uniform coating coverage. Various fixtures may be used to hold the substrate during the IAD deposition.

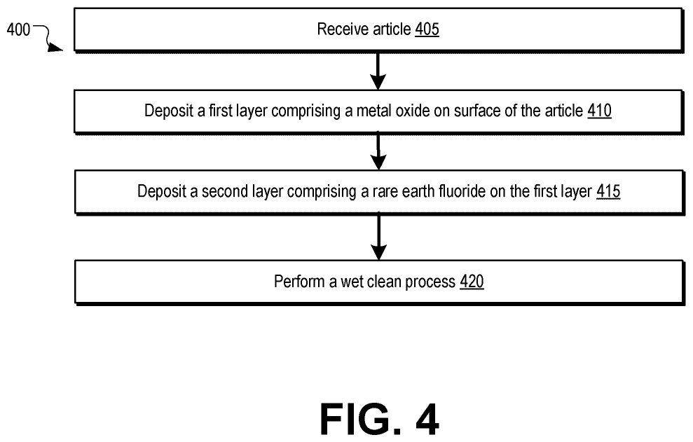

In FIG. 4 a method 400 according to an embodiment of the present disclosure is shown. The method 400 includes receiving an article or a chamber component in block 405. The chamber component may be made from a metal (such as aluminum, stainless steel), a ceramic (such as Y₂O₃, Al₂O₃, Y₃Al₅O₁₂ (YAG), and so forth), a metal-ceramic composite, a polymer, a polymer ceramic composite, mylar, polyester, or other suitable materials, and may further comprise materials such as AlN, Si, SiC, Al₂O₃, SiO₂, and so on.

In block 410, a first layer is deposited on the surface of the article. The first layer includes a metal oxide layer, such as aluminum oxide (Al₂O₃). The first layer may be deposited using an atomic layer deposition (ALD), a plasma spray process, ion assisted deposition (IAD), chemical vapor deposition, electron beam ion assisted deposition (EB-IAD), chemical vapor deposition, or a physical vapor deposition. The depositing of the first layer is performed until a target thickness is achieved. The target thickness may be about 10 nm to about 50 nm.

After the first layer is formed, then a second layer is deposited in block 415. The second layer includes a rare earth fluoride layer, which is deposited on the first layer. The second layer may be deposited in one of the depositing processes described in reference to block 410. The depositing of the second layer is performed until a target thickness is achieved. The target thickness may be about 15 nm to about 20 micron.

After forming the second layer, the depositing blocks 410 and 415 may be repeated to form a plurality of multi-layers on the article (not shown), such that the top layer is a rare earth fluoride layer.

In block 420, a wet clean process is performed to remove surface oxidation from the rare earth fluoride layer. The wet clean process may include placing the article in a bath including HF and water. The HF may have a concentration of about 0.5% to about 50% v/v. In another embodiment, the bath may include HF, HNO₃ and water. In yet another embodiment, the bath may include HNO₃ and water. The wet clean process may be performed for about 5 minutes to about 4 hours. In some embodiments, the wet clean process may include ultrasonication. The wet clean process may remove surface oxidation, contaminants (such as alkali metal (e.g., sodium or potassium)), or any other impurities found in the rare earth fluoride layer.

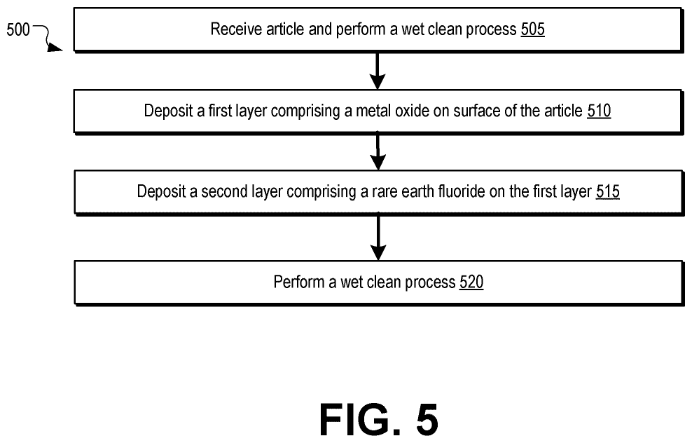

In FIG. 5 a method 500 according to an embodiment of the present disclosure is shown to refurbish a used part from the processing chamber. The method 500 includes receiving a used article or a used chamber component in block 505 and performing a wet clean process to remove any contaminants from the surface of the article/chamber component. The chamber component may be made from a metal (such as aluminum, stainless steel), a ceramic (such as Y₂O₃, Al₂O₃, Y₃Al₅O₁₂ (YAG), and so forth), a metal-ceramic composite, a polymer, a polymer ceramic composite, mylar, polyester, or other suitable materials, and may further comprise materials such as AlN, Si, SiC, Al₂O₃, SiO₂, and so on. The wet clean process includes placing the article in a bath including HF and water. The HF may have a concentration of about 0.5% to about 50% v/v. In another embodiment, the bath may include HF, HNO₃ and water. In yet another embodiment, the bath may include HNO₃ and water.

Blocks 510 to 520 are similar to those described in reference to FIG. 4. That is, in block 510, a first layer is deposited on the surface of the article. The first layer includes a metal oxide layer, such as aluminum oxide (Al₂O₃). The first layer may be deposited using an atomic layer deposition (ALD), a plasma spray process, ion assisted deposition (IAD), electron beam ion assisted deposition (EB-IAD), chemical vapor deposition, or a physical vapor deposition. The depositing of the first layer is performed until a target thickness is achieved. The target thickness may be about 10 nm to about 50 nm.

After the first layer is formed, then a second layer is deposited in block 515. The second layer includes a rare earth fluoride layer, which is deposited on the first layer. The second layer may be deposited in one of the depositing processes described in reference to block 410. The depositing of the second layer is performed until a target thickness is achieved. The target thickness may be about 15 nm to about 20 micron.

After forming the second layer, the depositing blocks 410 and 415 may be repeated to form a plurality of multi-layers on the article (not shown), such that the top layer is a rare earth fluoride layer. In block 520, a wet clean process is performed to remove surface oxidation from the rare earth fluoride layer. The wet clean process may include placing the article in a bath including HF and water. The HF may have a concentration of about 0.5% to about 50% v/v. In another embodiment, the bath may include HF, HNO₃ and water. In yet another embodiment, the bath may include HNO₃ and water.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

1. A method comprising:
depositing a first layer comprising a metal oxide on a surface of a chamber component;
depositing a second layer comprising a rare earth fluoride on the first layer to form a protective coating on the chamber component; and
removing surface oxidation on the rare earth fluoride using wet clean process.

2. The method of claim 1, wherein the second layer comprising the rare earth fluoride has at least about 95% purity of the rare earth fluoride.

3. The method of claim 1, wherein the second layer comprising the rare earth fluoride has at least about 98% purity of the rare earth compound.

4. The method of claim 1, wherein the metal oxide comprises aluminum oxide (Al₂O₃).

5. The method of claim 1, wherein the rare earth fluoride comprises yttrium fluoride (YF₃).

6. The method of claim 1, wherein the first layer has a thickness of about 10 nm to about 50 nm.

7. The method of claim 1, wherein the second layer has a thickness of about 100 nm to about 20 microns.

8. The method of claim 1, wherein the depositing is performed using a process of atomic layer deposition (ALD), ion assisted deposition (IAD), physical vapor deposition (PVD), or chemical vapor deposition (CVD).

9. The method of claim 1, wherein the protective coating comprises 0% to 2% of radicals comprising oxygen.

10. The method of claim 1, wherein the chamber component comprises a metal, a metal-ceramic composite, a ceramic, a polymer, or a polymer ceramic composite.

11. The method of claim 1, wherein the protective coating has uniform thickness.

12. The method of claim 1, wherein the first layer and the second layer have a thickness ratio of at least about 1:10.

13. A method comprising, sequentially,:
performing a wet clean process to remove surface contaminants from a surface of a chamber component;
depositing a first layer comprising a metal oxide on the surface of the chamber component; and
depositing a second layer comprising a rare earth fluoride on the first layer to form a protective coating on the chamber component.

14. The method of claim 13, wherein the wet clean process comprises placing the chamber component in a bath.

15. The method of claim 14, wherein the bath comprises hydrogen fluoride (HF) and water.

16. The method of claim 15, wherein the HF has a concentration of about 0.5% to about 50% v/v.

17. The method of claim 14, wherein the bath comprises nitric acid (HNO₃) and water.

18. The method of claim 13, wherein the first layer comprises a metal oxide layer.

19. The method of claim 13, further comprising removing surface oxidation on the rare earth fluoride using an additional wet clean process.

20. The method of claim 13, further comprising repeating the depositing of the first layer and the depositing of the second layer to form a plurality of multi-layers on the chamber component to form the protective coating, wherein a top layer of the plurality of multi-layers is a rare earth fluoride layer.
